(19) United States
(12) Patent Application Publication
(10) Pub. No.: US 2011/0177678 A1
(43) Pub. Date: Jul. 21, 2011

(54) METHOD FOR MANUFACTURING NITRIDE SEMICONDUCTOR DEVICE

(75) Inventors: Akihito Ohno, Tokyo (JP); Masayoshi Takemi, Tokyo (JP); Takahiro Yamamoto, Tokyo (JP)

(73) Assignee: MITSUBISHI ELECTRIC CORPORATION, Tokyo (JP)

(21) Appl. No.: 12/889,472

(22) Filed: Sep. 24, 2010

(30) Foreign Application Priority Data
Jan. 19, 2010 (JP) 2010-009288

(51) Int. Cl. H01L 21/20

(52) U.S. Cl. 438/478; 257/E21.09; 977/755

(57) ABSTRACT

A method for manufacturing a nitride semiconductor device includes forming an n-type nitride-based semiconductor layer on a substrate; forming an active layer of a nitride-based semiconductors including In on the n-type nitride-based semiconductor layer using ammonia and a hydrazine derivative as group-V element source materials and a carrier gas including hydrogen; and forming a p-type nitride-based semiconductor layer on the active layer using ammonia and a hydrazine derivative as group-V element source materials.

### BACKGROUND OF THE INVENTION

1. Field of the Invention

The present invention relates to a method for manufacturing a nitride semiconductor device composed of a group III-V nitride-based semiconductor. More specifically, the present invention relates to a method for manufacturing an excellent nitride semiconductor device through simple processes.

2. Background Art

As a material for light-emitting elements or electronic devices, such as semiconductor laser elements and light-emitting diodes, group III-V nitride-based semiconductors have been actively studies and developed. Utilizing the characteristics thereof, blue light-emitting diodes, green light-emitting diodes; and blue-violet semiconductor lasers as the light sources for high-density optical disks have already been in practical use.

As a group-V material gas in the crystal growth of nitride-based semiconductors ammonia (NH₃) is widely used. InGaN used for the active layer of a light-emitting element is not crystallized unless it is grown at about 900° C. or lower, because In is easily re-vaporized from the surface. Since the decomposition efficiency of NH₃ is extremely low in this temperature range, a large quantity of NH₃ is required. Moreover, since the V/III ratio must be practically elevated, and the growing speed must be lowered, there has been a problem wherein unintended impurities are mixed in the crystal.

When blue to green visible light is emitted, the In component of InGaN used in the active layer must be 20% or more. In this case, InGaN must be grown at about 800° C. or lower, and a more quantity of NH₃ is required. Furthermore, since InGaN having 20% or more In component is easily deteriorated by heat, the active layer is deteriorated in the growing process of the clad layer and the contact layer grown on the InGaN active layer, or by heat treatment performed in the wafer processing to lower the light-emitting efficiency, there has been the problem wherein device characteristics are worsened.

In order to solve the above-described problems, methods wherein hydrazine, which has a high decomposition efficiency, is used as a group-V material gas in place of NH₃, have been disclosed (for example, refer to Japanese Patent Application Laid-Open No. 2001-144325). Furthermore, in order to reduce the thermal damage of active layers, methods wherein p-layers are grown at a temperature of 900° C. or lower, have been disclosed (for example, refer to Japanese Patent Application Laid-Open No. 2004-87565).

### SUMMARY OF THE INVENTION

However, by only using hydrazine as the group-V material gas, there has been a problem wherein the quality improvement of the InGaN active layer is insufficient, and especially light-emitting characteristics are deteriorated when visible light of blue to green is emitted. Moreover, even if the p-layer is grown at a temperature of 900° C. or lower, there has been another problem wherein the active layer is thermally damaged during high-temperature annealing at 800 to 1000° C. for activating Mg used as a p-type dopant, and light-emitting characteristics are degraded. This problem has significantly occurred in the region where the active layer wavelength exceeds blue color.

In view of the above-described problems, an object of the present invention is to provide a method for manufacturing an excellent nitride semiconductor device through simple processes.

According to the present invention, a method for manufacturing a nitride semiconductor device comprises: forming an n-type nitride-based semiconductor layer on a substrate; forming an active layer of a nitride-based semiconductor having In on the n-type nitride-based semiconductor layer by using ammonia and hydrazine derivative as group-V materials and a carrier gas having hydrogen; and forming a p-type nitride-based semiconductor layer on the active layer by using ammonia and hydrazine derivative as group-V materials.

The present invention makes it possible to manufacture an excellent nitride semiconductor device through simple processes.

Other and further objects, features and advantages of the invention will appear more fully from the following description.

### BRIEF DESCRIPTION OF THE DRAWINGS

FIG. 1 is a sectional view showing a nitride semiconductor device according to the first embodiment.

FIG. 2 is an enlarged sectional view showing the active layer of the nitride semiconductor device shown in FIG. 1.

FIG. 3 is a graph showing the NH₃/hydrazine supply mole ratio dependency of the resistivity of a p-type GaN layer.

FIG. 4 is a graph showing the hydrazine/group-III material supply mole ratio dependency of the resistivity of the p-type GaN layer.

FIG. 5 is a graph showing the growing temperature dependency of the carbon concentration in the p-type GaN layer.

FIG. 6 is a graph showing the result of photoluminescence (PL) measurement of an active layer according to the first embodiment.

FIG. 7 is a graph showing the carbon concentration dependency of the resistivity of the p-type GaN layer.

FIG. 8 is a sectional view showing a nitride semiconductor device according to the second embodiment.

FIG. 9 is an enlarged sectional view of the active layer in the nitride semiconductor device shown in FIG. 8.

FIG. 10 is a sectional view showing a nitride semiconductor device according to the third embodiment.

FIG. 11 is an enlarged sectional view of the active layer in the nitride semiconductor device shown in FIG. 10.

### DETAILED DESCRIPTION OF THE PREFERRED EMBODIMENTS

The embodiments of the present invention will be described below referring to the drawings. The same constituents will be donated by the same numerals and characters, and the description thereof will be omitted.

### First Embodiment

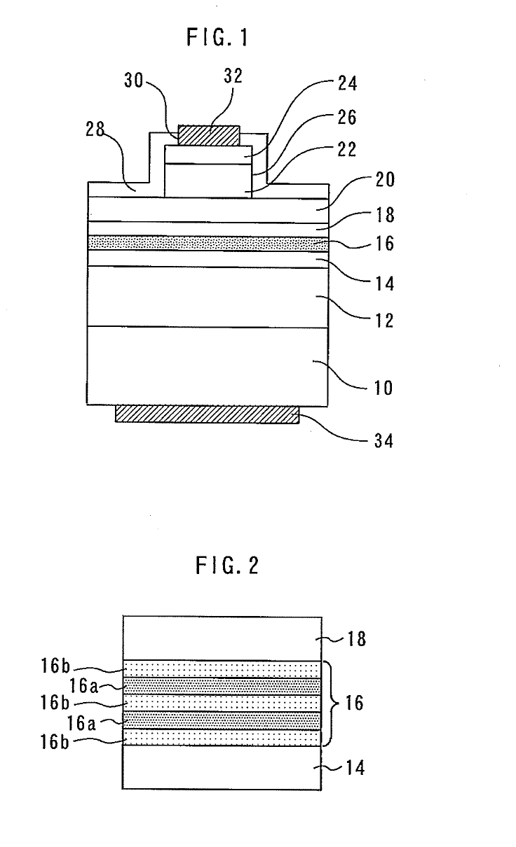

FIG. 1 is a sectional view showing a nitride semiconductor device according to the first embodiment. The nitride semiconductor device is a nitride-based semiconductor laser.

On the major surface (0001) of an n-type GaN substrate 10, an n-type Al_{0.03}Ga_{0.97}N clad layer 12 having a thickness of 2.0 μm, an n-type GaN light guide layer 14 having a thickness of 0.1 μm, an active layer 16, a p-type Al_{0.2}Ga_{0.8}N electron barrier layer 18 having a thickness of 0.02 μm, a p-type GaN light guide layer 20 having a thickness of 0.1 μm, a p-type Al_{0.03}Ga_{0.97}N clad layer 22 having a thickness of 0.5 μm, and a p-type GaN contact layer 24 having a thickness of 0.06 μm are sequentially formed.

The p-type Al_{0.03}Ga_{0.97}N clad layer 22 and the p-type GaN contact layer 24 constitute a waveguide ridge 26. The waveguide ridge 26 is formed on the central portion in the width direction of a resonator, and extends between the both cleaved surfaces that become the end surfaces of the resonator.

An SiO₂ film 28 is disposed on the sidewall of the waveguide ridge 26 and the exposed surface of the p-type GaN light guide layer 20. An opening 30 of the SiO₂ film 28 is disposed on the upper surface of the waveguide ridge 26, and the surface of the p-type GaN contact layer 24 is exposed from the opening 30. A p-side electrode 32 is formed on the exposed p-type GaN contact layer 24. An n-side electrode 34 is formed on the back face of the n-type GaN substrate 10.

FIG. 2 is an enlarged sectional view showing the active layer of the nitride semiconductor device shown in FIG. 1. The active layer 16 is a multiple quantum well structure wherein 2 pairs of In_{0.2}Ga_{0.8}N well layers 16a each having a thickness of 3.0 nm and GaN barrier layers 16b each having a thickness of 16.0 nm are alternately laminated.

A method for manufacturing a nitride semiconductor device according to the first embodiment will be described. As the method for growing crystals, an MOCVD method is used. As group-III materials, trimethyl gallium (TMG), trimethyl aluminum (TMA), and trimethyl indium (TMI), which are organic metal compounds, are used. As group-V materials, ammonia (NH₃) and 1,2-dimethylhydrazine (hydrazine derivative) are used. As an n-type impurity material, monosilane (SiH₄) is used; and as a p-type impurity material, cyclopentadienyl magnesium (CP₂Mg) is used. As a carrier gas for these materials, hydrogen (H₂) gas or nitrogen (N₂) gas is used. However, as the p-type impurity, Zn or Ca may also be used in place of Mg.

First, the n-type GaN substrate 10, whose surface has been previously cleaned by thermal cleaning or the like, is prepared. Then, after placing the n-type GaN substrate 10 in the reaction furnace of an MOCVD apparatus, the temperature of the n-type GaN substrate 10 is elevated to 1000° C. while supplying NH₃. Next, the supply of TMG, TMA, and SiH₄ is started to form the n-type Al_{0.03}Ga_{0.97}N clad layer 12 on the major surface of the n-type GaN substrate 10. Next, the supply of TMA is stopped to form the n-type GaN light guide layer 14. Next, the supply of TMG and SiH₄ is stopped, and the temperature of the n-type GaN substrate 10 is lowered to 750° C.

Next, as the carrier gas, a small quantity of H₂ gas is mixed to N₂ gas, and ammonia, 1,2-dimethylhydrazine, TMG, and TMI are supplied to form the In_{0.2}Ga_{0.8}N well layer 16a. Then, the supply of TMI is stopped, and ammonia, 1,2-dimethylhydrazine, and TMG are supplied to form the GaN barrier layer 16b. Two pairs of these are alternately laminated to form the active layer 16 having the multiple quantum well (MQW) structure. Here, the flow rate of H₂ gas is within a range between 0.1% and 5% of the flow rate of the total gas.

Next, the temperature of the n-type GaN substrate 10 is elevated again from 750° C. to 1000° C. while supplying NH₃ having a flow rate of 1.3×10⁻¹ mol/min and nitrogen gas having a flow rate of 20 L/min. Then, using a 1:1 mixed gas of hydrogen gas and nitrogen gas as the carrier gas, TMG having a flow rate of 2.4×10⁻⁴ mol/min, TMA having a flow rate of 4.4×10⁻⁵ mol/min, and CP₂Mg having a flow rate of 3.0×10⁻⁷ mol/min as group-III materials; and 1,2-dimethylhydrazine having a flow rate of 1.1×10⁻³ mol/min in addition to NH₃ as group-V materials to form the p-type Al_{0.2}Ga_{0.6}N electron barrier layer 18. In this case, the mole ratio of 1,2-dimethylhydrazine supplied to the group-III materials is 3.9, and the mole ratio of NH₃ supplied to 1,2-dimethylhydrazine is 120.

Next, the supply of TMA is stopped, and TMG having a flow rate of 1.2×10⁻⁴ mol/min and CP₂Mg having a flow rate of 1.0×10⁻⁷ mol/min are supplied as group-III materials; and 1,2-dimethylhydrazine having a flow rate of 1.1×10⁻³ mol/min are supplied in addition to NH₃ as group-V materials together with the carrier gas to form the p-type GaN light guide layer 20.

Next, the supply of TMA is started again, and TMG having a flow rate of 2.4×10⁻⁴ mol/min, TMA having a flow rate of 1.4×10⁻⁵ mol/min, and CP₂Mg having a flow rate of 3.0×10⁻⁷ mol/min are supplied as group-III materials; and NH₃ and 1,2-dimethylhydrazine are supplied as group-V materials to form the p-type Al_{0.03}Ga_{0.37}N clad layer 22. In this case, the mole ratio of 1,2-dimethylhydrazine supplied to the group-III materials is 4.3, and the mole ratio of NH₃ supplied to 1,2-dimethylhydrazine is 120. The carbon concentration in the p-type Al_{0.03}Ga_{0.97}N clad layer 22 is 1×10¹⁸ cm⁻⁵ or less.

Next, the supply of TMA is stopped, and TMG having a flow rate of 1.2×10⁻⁴ mol/min and CP₂Mg having a flow rate of 9.0×10⁻⁷ mol/min are supplied as group-III materials; and 1,2-dimethylhydrazine having a flow rate of 1.1×10⁻⁵ mol/min are supplied in addition to NH₃ as group-V materials together with the carrier gas to form a p-type GaN contact layer 24. In this case, the mole ratio of 1,2-dimethylhydrazine supplied to the group-III materials is 9.4, and the mole ratio of NH₃ to 1,2-dimethylhydrazine is 120.

Next, the supply of TMG, which is the group-III material, and CP₂Mg, which is the p-type impurity material, is stopped, and the system is cooled to about 300° C. while supplying group-V materials. Then, the supply of the group-V materials is stopped, and the system is cooled to a room temperature. When the supply of TMG and CP₂Mg is stopped, the system may be cooled to about 300° C. while stopping the supply of NH₃, and while supplying 1,2-dimethylhydrazine alone; or the supply of NH₃ and 1,2-dimethylhydrazine may be simultaneously stopped.

After the above-described crystal growing, a resist is applied onto the entire surface of the p-type GaN contact layer 24, and by lithography, a resist pattern corresponding to the shape of the mesa-like portion is formed. By reactive ion etching (RIE) using the resist pattern as a mask, the area from the p-type GaN contact layer 24 to the middle of the p-type Al_{0.03}Ga_{0.97}N clad layer 22 is etched to form the waveguide ridge 26 that becomes a light waveguide structure. As an etching gas for RIE, for example, a chlorine-based gas is used.

Next, leaving the resist pattern, the SiO₂ film 28 having a thickness of 0.2 μm is formed on the entire surface of the n-type GaN substrate 10 using, for example, CVD, vacuum vapor deposition, and sputtering. Then, at the same time of the removal of the resist pattern, the SiO₂ film 28 on the waveguide ridge 26 is removed by a method referred to as a liftoff method. Thereby, the opening 30 is formed in the SiO₂ film 28 on the waveguide ridge 26.

Next, a Pt film and an Au film are sequentially formed on the p-type GaN contact layer 24 using vacuum vapor deposition. Thereafter, a resist (not shown) is applied and lithography and wet etching or dry etching are carried out to form the p-side electrode 32 in ohmic contact with the p-type GaN contact layer 24.

Next, a Ti film, a Pt film, and an Au film are sequentially formed on the back face of the n-type GaN substrate 10 by vacuum vapor deposition to form the n-side electrode 34. Next, the n-type GaN substrate 10 is processed into bar-shaped portions by cleavage or the like to form both end planes of the resonator. Then, after applying coating onto the end planes of the resonator, and the bar portions are cleaved into chips to manufacture the nitride semiconductor device according to the first embodiment.

In the above-described manufacturing method, a mixed gas of ammonia and 1,2-dimethylhydrazine as group-V materials to form the active layer 16. Thereby, an effective V/III ratio can be achieved even at a low growing temperature of 900° C. or lower, and the generation of N holes, which is a crystal fault, can be suppressed, and the mixing of impurities can by reduced. The manufacturing method according to the present embodiment can be applied not only to the InGaN quantum well structure, but also to In-containing active layers.

In addition, by adding several percent H₂ to the carrier gas, an etching function works in the growth of InGaN, and the segregation of In can be reduced to grow a quantum well structure having favorable optical properties.

Also, SiH₄ may be introduced into the InGaN active layer. For example, by doping Si to have a carrier concentration of 1×10¹⁸ cm⁻³, Si acts so as to bury N holes, and spot defects to become non-light emitting centers are reduced and the mixing of impurities are suppressed to further improve crystallinity. When emitting of light having shorter wavelength than blue wherein the In composition exceeds 20%, since growing is performed at lower temperatures, the efficiency of decomposing the group-V materials is lowered, and since N holes are easily generated in the InGaN crystals, the effect of crystallinity improvement by Si doping becomes further significant.

Next, the reason why both NH₃ and hydrazine derivatives (e.g., 1,2-dimethylhydrazine) are used in forming the p-type nitride-based semiconductor layer will be described.

When the p-type nitride-based semiconductor layer is formed, if only NH₃ is used as a group-V material, H radicals formed from NH₃ is incorporated in crystals in the p-type nitride-based semiconductor layer, and the H radicals react with the p-type impurities to generate H passivation (lowering of the activation of p-type impurities). Therefore, a heat treatment process for activation is required, and there is a problem wherein the escape of N occurs from the outermost surface of the crystals by heat treatment, and the quality of crystals is lowered. In addition, there is another problem wherein the active layer is damaged by heat treatment, and light-emitting characteristics are lowered.

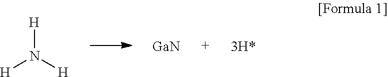

Therefore, when the group-V material is changed from ammonia gas to dimethylhydrazine (UDMHy), CH₃ radicals produced from UDMHy react with H radicals, and the H radicals produced from UDMHy are not incorporated in the crystals in the p-type nitride-based semiconductor layer.

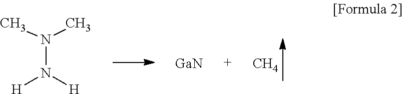

However, since trimethyl gallium (TMGa), which is an organic metal compound, is used as the group-III material, CH₃ radicals are liberated from TMGa, and unless the CH₃ radicals are exhausted as CH₄, the CH₃ radicals are incorporated in the crystals to elevate carbon concentration of the crystals, and elevate the resistivity of the p-type nitride-based semiconductor layer.

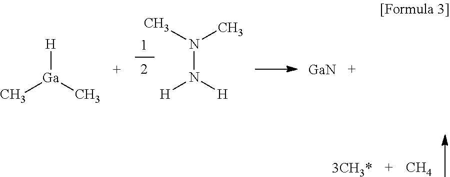

Therefore, when the V-group material is completely changed from ammonia gas to dimethylhydrazine, since H radicals, which are required in producing CH₄ from CH₃ radicals, become insufficient, in the present embodiment, a prescribed quantity of NH₃ that can supply the required quantity of H radicals to produce CH₄ is added.

Specifically, when the p-type nitride-based semiconductor layer is formed from dimethylhydrazine, firstly in order to lower the concentration of carbon incorporated in the crystals, in other words, in order to suppress the incorporation of compensated carbon by the accepter, H radicals required to exhaust CH₃ radicals liberated from dimethylhydrazine as CH₄ is supplied from NH₃.

However, if the quantity of H radicals produced from NH₃ is excessively large, H-passivation occurs; therefore, the supply quantity of NH₃, which is the supply source of H radicals, is made to be requisite minimum.

As described above, by supplying a prescribed flow rate of a mixed gas of NH₃ and 1,2-dimethylhydrazine as group-V materials when the p-type nitride-based semiconductor layer is formed, the occurrence of H-passivation can be suppressed, and the p-type nitride-based semiconductor layer having a low concentration of contained carbon and having a low electrical resistivity in an as-grown state can be formed. Therefore, since heat treatment processes for activating Mg used as a p-type dopant can be omitted, and thermal damage to the active layer can be reduced, an excellent nitride semiconductor device can be manufactured using simple processes.

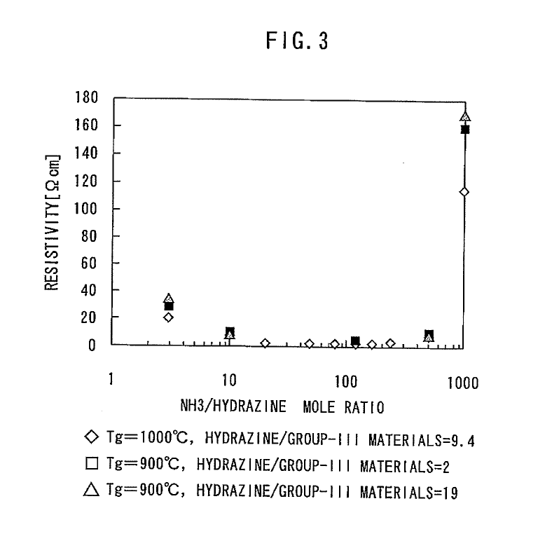

FIG. 3 is a graph showing the NH₃/hydrazine supply mole ratio dependency of the resistivity of a p-type GaN layer. The NH₃/hydrazine supply mole ratio means the supply mole flow rate of NH₃ to the supply mole flow rate of hydrazine. As the carrier gas, a mixed gas of nitrogen gas and hydrogen gas in a ratio of 1:1 was used. The case when the growing temperature is 1000° C. and the hydrazine/group-III material supply mole ratio is 9.4; the case when the growing temperature is 900° C. and the hydrazine/group-III material supply mole ratio is 2; and the case when the growing temperature is 900° C. and the hydrazine/group-III material supply mole ratio is 19 are shown. The hydrazine/group-III material supply mole ratio means the supply mole flow rate of hydrazine to the supply mole flow rate of the group-III material.

As a result, when the NH₃/hydrazine supply mole ratio becomes 10 or less, since the supply of the H radicals becomes insufficient and the carbon concentration in the crystal is elevated, the resistance is elevated. On the other hand, when the NH₃/hydrazine supply mole ratio is between 500 and 1000, the resistivity is sharply elevated. This is because H passivation is caused when H is incorporated into the crystal by the excessive supply of NH₃. Therefore, the range of the NH₃/hydrazine supply mole ratios is preferably between 10 and 1000 inclusive, and more preferably between 20 and 500 inclusive.

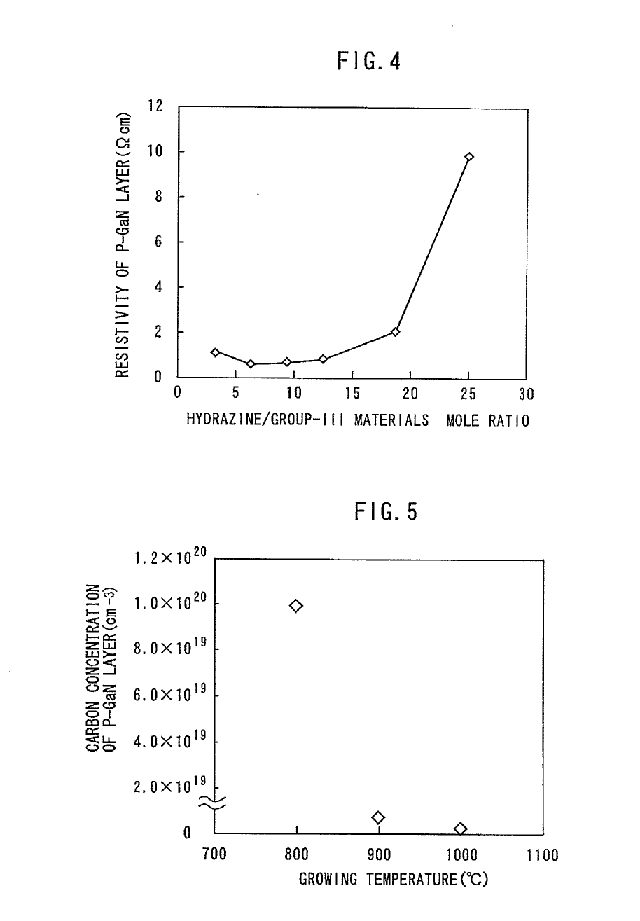

FIG. 4 is a graph showing the hydrazine/group-III material supply mole ratio dependency of the resistivity of the p-type GaN layer. The growing temperature was 1000° C., the NH₃/hydrazine supply mole ratio was 120, and a mixed gas of nitrogen gas and hydrogen gas in a ratio of 1:1 was used as the carrier gas.

As a result, resistivity is sharply elevated between the hydrazine/group-III material supply mole ratios 20 and 25. This is caused by the elevation of carbon concentration in the crystal. On the other hand, if the hydrazine/group-III material supply mole ratio is less than 1, group-V holes are produced in the crystal, and crystal defection is caused. Therefore, when the p-type GaN layer is formed, the supply mole ratio of hydrazine to organic metal compound is preferably 1 or more and less than 25, more preferably 3 or more to 15 or less.

FIG. 5 is a graph showing the growing temperature dependency of the carbon concentration in the p-type GaN layer. The growing temperature is the same as the temperature of the substrate. The hydrazine/group-III material supply mole ratio was 9.4, the NH₃/hydrazine supply mole ratio was 120, and a mixed gas of nitrogen gas and hydrogen gas in a ratio of 1:1 was used as the carrier gas.

As a result, the carbon concentration in the crystal was sharply lowered at temperatures between 800° C. and 900° C. In addition, when the growing temperature was lowered, the decomposition of NH₃ was reduced, and no CH₃ radicals were released as CH₄. This is considered that the CH₃ radicals are incorporated in the crystals. On the other hand, the temperature at which the crystal growth of p-type GaN is feasible is lower than 1200° C. Therefore, when the p-type GaN layer is formed, the temperature of the n-type GaN substrate 10 is preferably 800° C. or higher and lower than 1200° C., and more preferably 900° C. or higher and lower than 1100° C.

FIG. 6 is a graph showing the result of photoluminescence (PL) measurement of an active layer according to the first embodiment. In FIG. 6, the abscissa is the growing temperature of the p-type clad layer; and the ordinate is the PL intensity of the active layer. Here, the temperature at which thermal damage to the active layer occurs was confirmed by elevating the growing temperature of the p-type clad layer grown on the active layer from 760° C. to 1150° C.

As a result, although the PI, intensity of the active layer is little changed until the growing temperature of the p-type clad layer was 1100° C., the PI, intensity was sharply lowered when the growing temperature exceeded 1100° C. This was because the active layer was damaged by heat exceeding 1100° C., and light-emitting characteristics were degraded. In addition, the thermal damage to the active layer and the carbon concentration in the p-type nitride-based semiconductor layer must be taken in consideration. Therefore, the growing temperature of the p-type nitride-based semiconductor layer is preferably 800° C. or higher and lower than 1100° C., more preferably 900° C. or higher and lower than 1100° C.

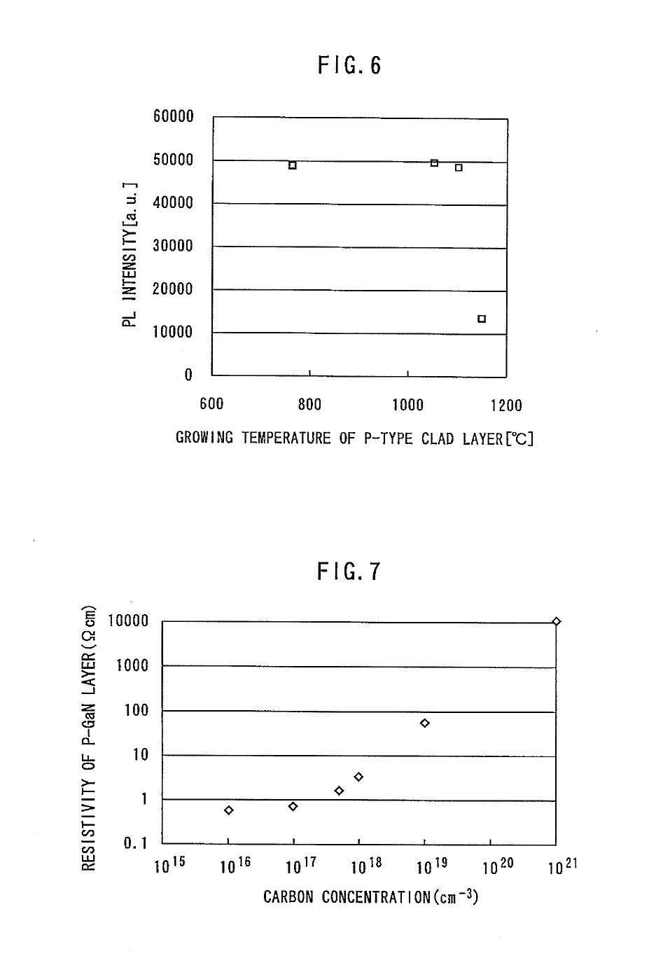

FIG. 7 is a graph showing the carbon concentration dependency of the resistivity of the p-type GaN layer. The detection limit of carbon is 1×10¹⁸ cm⁻³. In order to achieve a low resistivity so as to be used as a device, the carbon concentration must be 1×10¹⁸ cm⁻³ or lower.

Although it is preferable that no carbon is contained in the p-type GaN layer, when hydrazine is used, even a small quantity of carbon is incorporated in the p-type GaN layer. However, the carbon concentration of the p-type GaN layer can be made to be 1×10¹⁸ cm⁻³ or lower by selecting the manufacturing conditions according to the present embodiment.

Also when the p-type nitride-based semiconductor layer is formed, a mixed gas of hydrogen gas and nitrogen gas, wherein the volume composition ratio of the hydrogen gas is x (0≦x≦1), and the volume composition ratio of the nitrogen gas is 1−x, is used as the carrier gas. Specifically, the carrier gas for forming the p-type nitride-based semiconductor layer may be any of nitrogen gas alone, a mixed gas of nitrogen gas and hydrogen gas, and hydrogen gas alone. Here, when the temperature of the substrate is about 1000° C., hydrogen gas is not dissociated and present as the state of hydrogen molecules, and is not incorporated in the crystal. Therefore, H radicals incorporated in the crystal are considered to be mainly H radicals dissociated from NH₃, so the p-type nitride-based semiconductor layer having a low resistivity can be formed even if the carrier gas is hydrogen gas alone. For example, a mixed gas of a flow rate of 10 L/min of hydrogen gas and a flow rate of 10 L/min of nitrogen gas in the ratio of 1:1 can be used ad the carrier gas.

### Second Embodiment

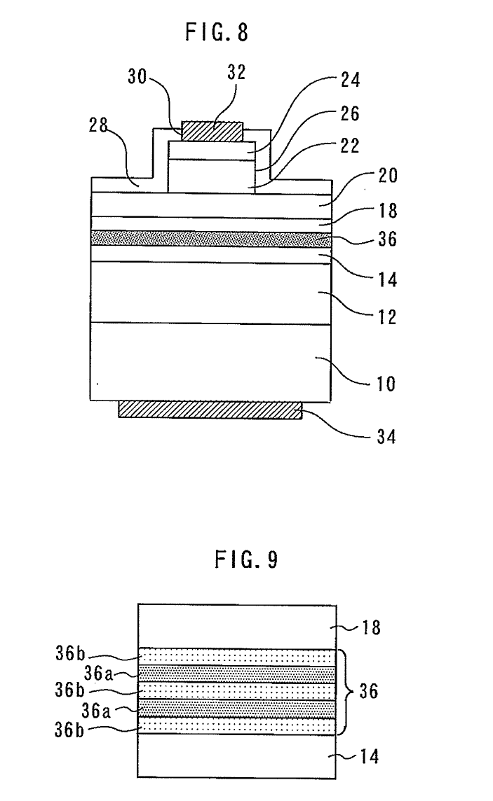

FIG. 8 is a sectional view showing a nitride semiconductor device according to the second embodiment. FIG. 9 is an enlarged sectional view of the active layer in the nitride semiconductor device shown in FIG. 8. In place of the active layer 16 in the first embodiment, an active layer 36 is used. Other configurations are same as those in the first embodiment.

The active layer 36 is a multiple quantum well structure wherein 2 pairs of Al_{0.01}In_{0.21}Ga_{0.78}N well layers 36a each having a thickness of 3.0 nm and Al_{0.01}In_{0.015}Ga_{0.975}N barrier layers 36b each having a thickness of 16.0 nm are alternately laminated.

A method for manufacturing the active layer 36 will be described. First, the temperature of the n-type GaN substrate 10 is elevated to 750° C. while supplying NH₃ gas. Next, as the carrier gas, a small quantity of H₂ gas is mixed to N₂ gas, and ammonia, 1,2-dimethylhydrazine, TMG, TMI, and TMA are supplied to form the Al_{0.01}In_{0.21}Ga_{0.78}N well layer 36a and the Al_{0.01}In_{0.015}Ga_{0.975}N barrier layer 36b. By alternately laminating 2 pairs of these, the active layer 36, which is a multiple quantum well (MOW) structure, is formed.

In the present embodiment, since the active layer 36 is composed of AlInGaN, and the bonding force of the crystal is improved in comparison with the active layer composed of InGaN, the degradation of the crystal by heat can be prevented. As for the rest, the same effects as those in the first embodiment can be achieved.

### Third Embodiment

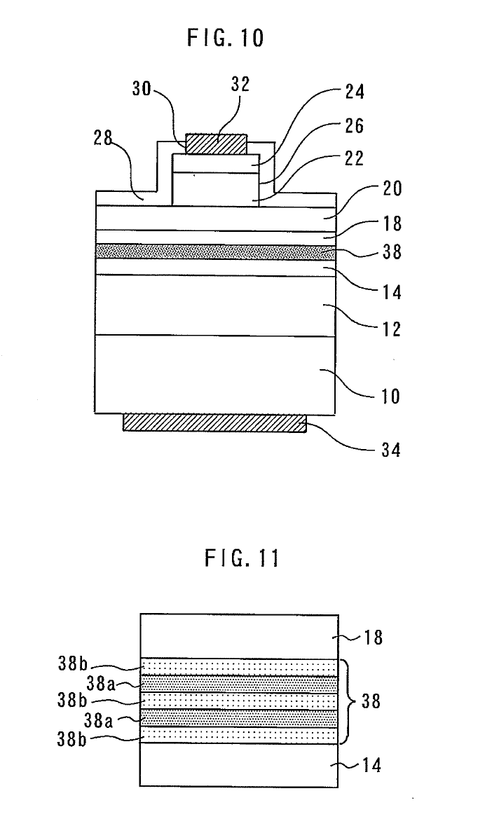

FIG. 10 is a sectional view showing a nitride semiconductor device according to the third embodiment. FIG. 11 is an enlarged sectional view of the active layer in the nitride semiconductor device shown in FIG. 10. In place of the active layer 16 in the first embodiment, an active layer 38 is used. Other configurations are same as those in the first embodiment.

The active layer 38 is a multiple quantum well structure wherein 2 pairs of In_{0.2}Ga_{0.8}N well layers 38a each having a thickness of 3.0 nm and Al_{0.03}In_{0.002}Ga_{0.968}N barrier layers 38b each having a thickness of 16.0 nm are alternately laminated.

A method for manufacturing the active layer 38 will be described. First, the temperature of the n-type GaN substrate 10 is elevated to 750° C. while supplying NH₃ gas. Next, as the carrier gas, a small quantity of H₂ gas is mixed to N₂ gas, and ammonia, 1,2-dimethylhydrazine, TMG, and TMI are supplied to form the In_{0.2}Ga_{0.8}N well layer 38a. Then, ammonia, 1,2-dimethylhydrazine, TMG, TMI, and TMA are supplied to form the Al_{0.03}In_{0.02}Ga_{0.968}N barrier layer 38b. By alternately laminating 2 pairs of these, the active layer 38, which is a multiple quantum well (MQW) structure, is formed.

Since the well layer 38a is composed of InGaN, which is a ternary mixed crystal having excellent crystallinity, and the barrier layer 38b is composed of AlInGaN, which is a quaternary mixed crystal having excellent heat resistance, a light-emitting element having more excellent light-emitting characteristics can be obtained. As for the rest, the same effects as those in the first embodiment can be achieved.

In addition, it is preferable that the well layer 38a has a compressive strain because of being composed of InGaN having an a-axis length longer than GaN of the substrate 10; and the barrier layer 38b has a tensile strain because of being composed of InAlGaN having an a-axis length shorter than GaN of the substrate 10. Normally, the well layer of the active layer that emits blue-violet or blue light has a large compressive strain, and the strain quantity is enlarged when the wavelength becomes longer. Then, when the wavelength becomes longer than the wavelength of blue, misfit dislocation is significantly occurred by strain. Whereas, by using the barrier layer 38b having a tensile strain, the occurrence of misfit dislocation can be reduced.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-009288, filed on Jan. 19, 2010 including specification, claims, drawings and summary, on which the Convention priority of the present application is based, are incorporated herein by reference in its entirety.

1. A method for manufacturing a nitride semiconductor device comprising:
forming an n-type nitride-based semiconductor layer on a substrate;
forming an active layer of a nitride-based semiconductors including In on the n-type nitride-based semiconductor layer using ammonia and a hydrazine derivative as group-V element source materials and a carrier gas including hydrogen; and
forming a p-type nitride-based semiconductor layer on the active layer using ammonia and a hydrazine derivative as group-V element source materials.

2. The method for manufacturing a nitride semiconductor device according to claim 1, including introducing Si into the active layer as a dopant impurity.

3. The method for manufacturing a nitride semiconductor device according to claim 1, wherein the ratio of mole flow rate of ammonia to mole flow rate of the hydrazine derivative is between 10 and 1000, inclusive, in forming the p-type nitride-based semiconductor layer.

4. The method for manufacturing a nitride semiconductor device according to claim 1, wherein organic metal compounds are used as group-III element source materials and the ratio of the mole ratio of the hydrazine derivative to the mole ratio of the organic metal compound is at least 1 and less than 25 in forming the p-type nitride-based semiconductor layer.

5. The method for manufacturing a nitride semiconductor device according to claim 1, wherein temperature of the substrate is at least 900° C. and lower than 1100° C., in forming the p-type nitride-based semiconductor layer.

6. The method for manufacturing a nitride semiconductor device according to claim 1, wherein the active layer is a multiple quantum well structure having well layers of InGaN and barrier layers of InAlGaN.

7. The method for manufacturing a nitride semiconductor device according to claim 6, wherein each well layer has a compressive strain and each barrier layer has a tensile strain.
